(19) United States
(12) Patent Application Publication
(10) Pub. No.: US 2026/0150434 A1
(43) Pub. Date: May 28, 2026

(54) Optoelectronic Device and the Fabrication Thereof

(71) Applicant: Sensor Electronic Technology, Inc., Columbia, SC (US)

(72) Inventors: Mohamed Lachab, West Columbia, SC (US); Rakesh B. Jain, Elgin, SC (US)

(21) Appl. No.: 19/401,657

(22) Filed: Nov. 26, 2025

Related U.S. Application Data
(60) Provisional application No. 63/726,215, filed on Nov. 27, 2024.

(51) Int. Cl. H10H 20/01; H10F 71/00; H10F 77/124; H10F 77/14; H10F 77/20; H10F 77/30; H10F 77/40; H10F 77/70; H10H 20/80; H10H 20/812; H10H 20/825; H10H 20/831; H10H 20/832; H10H 20/84

(52) U.S. Cl. CPC H10H 20/019; H10F 71/139; H10F 77/1246; H10F 77/146; H10F 77/206; H10F 77/306; H10F 77/413; H10F 77/707; H10H 20/812; H10H 20/825; H10H 20/8312; H10H 20/835; H10H 20/84; H10H 20/882

(57) ABSTRACT

An optoelectronic device can include a p-type contact and an optoelectronic heterostructure located on the p-type contact. The optoelectronic heterostructure can include a p-type semiconductor layer, an n-type semiconductor layer, and an active region located between the p-type semiconductor layer and the n-type semiconductor layer. An n-type contact can be located on a surface of the optoelectronic heterostructure. Additionally, three-dimensional nanostructures also can be located on the surface of the optoelectronic heterostructure. At least one of: a density, a size, or a shape of the three-dimensional nanostructures can be substantially uniform across the surface of the optoelectronic heterostructure. A method of fabricating the optoelectronic device can include forming the three-dimensional nanostructures on a surface of the heterostructure exposed by removal of a growth substrate. The optoelectronic device can be configured to operate as a deep ultraviolet light emitting device.

### REFERENCE TO RELATED APPLICATIONS

The current application claims the benefit of U.S. Provisional Application 63/726,215, filed on 27 Nov. 2024, which is hereby incorporated by reference.

### TECHNICAL FIELD

The disclosure relates generally to optoelectronic devices, and more particularly, to a group III nitride-based optoelectronic device and a method for the fabrication thereof.

### BACKGROUND ART

Substrate transfer technology has been proposed to boost the wall plug efficiency (WPE) of deep-ultraviolet (DUV) light emitting diodes (LEDs), which is currently limited to ˜6%. The technology has been proposed for the fabrication of nitride-based vertical conduction DUV emitters to achieve high optical power devices, with low forward voltage and improved lifetime performance.

To realize vertical type semiconductor DUV emitters, the epitaxial structures grown on substrates that usually exhibit low electrical and/or thermal conductivity, such as sapphire, are conventionally bonded to thermally conductive substitute carriers, followed by the removal of the original growth substrate. The most common technique to detach the epitaxial layers is laser lift-off (LLO), although chemical etching can be applied in certain cases like with silicon carbide (SiC) substrates.

The prevention of material cracking in such epitaxial structures is, however, a challenge with the LLO approach. After substrate removal, the exposed N-face layer surface can be textured or roughened using wet etching or laser micro-machining. These additional process steps can increase the amount of light emitted by the LEDs by up to two-folds through enhancement of light extraction efficiency. However, wet etching is known to produce random surface features, while laser micro-machining often is not cost-effective or scalable for mass production.

The formation of n-type ohmic contacts is another challenge for the fabrication of vertical DUV LEDs. Most commonly, the n-type contacts are deposited post-substrate lift-off. However, since the evaporated n-type metal stack requires annealing at temperatures above 800° C., achieving ohmic contacts strongly depends on the thermal stability of the bonding material between the epitaxial structure and the substitute carrier.

One research group proposed AlGaN-based high power vertical UV-C LEDs consisting of a Ga-face ohmic n-type contact structure, where the n-type AlGaN layer is exposed by etching through the p-type layers. Laser annealing is another option to achieve localized annealing of the n-type contacts but care should be taken not to damage the epitaxial layers or generate new defects, which may be detrimental to the performance of the devices.

### SUMMARY OF THE INVENTION

Aspects of the invention provide an optoelectronic device and a method for the fabrication thereof. Embodiments provide a solution for fabricating an optoelectronic device which includes an improved solution for transferring a nitride-based light emitting structure from an initial (e.g., growth) substrate to a permanent (e.g., substitute) substrate.

In embodiments, the nitride-based light emitting structure is a light emitting diode (LED). In more particular embodiments, the LED is an ultraviolet LED. In still more particular embodiments, the ultraviolet LED is a deep ultraviolet LED.

In embodiments, a silicon oxynitride (SiOₓN_{y}) interlayer can be used as a thermally stable layer for materials bonding as part of the transfer. In embodiments, the interlayer is formed of silicon dioxide or silicon nitride. In embodiments, an intermediate layer can be used as a thermally stable layer for materials bonding as part of the transfer. In embodiments, the intermediate layer can include hydrogen. In embodiments, a hydrogen silsesquioxane (HSQ, HSiO_{3/2}) intermediate layer can be used as a thermally stable oxide layer for the bonding.

In embodiments, nano-structures are re-grown on the exposed N-face surface of a group III nitride layer to enhance the intensity of light emitted from the light emitting structure. The nano-structures can be uniformly fabricated with a density and/or distribution of the structures precisely controlled, include self-organized three-dimensional islands, and/or the like. In embodiments, n-type ohmic contacts can be formed on the N-face surface of the group III nitride layer.

A first aspect of the invention provides an optoelectronic device comprising: a permanent substrate; a p-type contact located on the permanent substrate; at least one optoelectronic heterostructure located on the p-type contact, the at least one optoelectronic heterostructure including a p-type semiconductor layer, an n-type semiconductor layer, and an active region located between the p-type semiconductor layer and the n-type semiconductor layer; at least one n-type contact located on a surface of the at least one optoelectronic heterostructure; and a plurality of three-dimensional nanostructures located on the surface of the at least one optoelectronic heterostructure, wherein at least one of: a density, a size, or a shape of the three-dimensional nanostructures is substantially uniform across the surface of the at least one optoelectronic heterostructure.

A second aspect of the invention provides a deep ultraviolet light emitting device comprising: a p-type contact; a heterostructure located on the p-type contact, the heterostructure including a p-type semiconductor layer, an n-type semiconductor layer, and an active region located between the p-type semiconductor layer and the n-type semiconductor layer, wherein the active region is configured to emit deep ultraviolet radiation; at least one n-type contact located on a surface of the heterostructure; and a plurality of three-dimensional nanostructures located on the surface of the heterostructure, wherein at least one of: a density, a size, or a shape of the three-dimensional nanostructures is substantially uniform across the surface of the heterostructure.

A third aspect of the invention provides a method of fabricating an optoelectronic device, the method comprising: removing a growth substrate from a wafer, the wafer comprising a heterostructure located on the growth substrate, the heterostructure including: a buffer layer located on the growth substrate, an n-type semiconductor layer located on the buffer layer, a p-type semiconductor layer located on the n-type semiconductor layer, and an active region located between the n-type semiconductor layer and the p-type semiconductor layer; and forming a plurality of three-dimensional nanostructures on a surface of the heterostructure exposed by removal of the growth substrate, wherein at least one of: a density, a size, or a shape of the three-dimensional nanostructures is substantially uniform across the surface of the heterostructure.

The illustrative aspects of the invention are designed to solve one or more of the problems herein described and/or one or more other problems not discussed.

### BRIEF DESCRIPTION OF THE DRAWINGS

These and other features of the disclosure will be more readily understood from the following detailed description of the various aspects of the invention taken in conjunction with the accompanying drawings that depict various aspects of the invention.

FIG. 1 shows an illustrative wafer for fabricating optoelectronic device(s) according to embodiments.

FIG. 2 shows an illustrative intermediate heterostructure for fabricating the optoelectronic device(s) from the wafer according to embodiments.

FIG. 3 shows an illustrative subsequent intermediate heterostructure for fabricating the optoelectronic device(s) from the wafer according to embodiments.

FIG. 4 shows various illustrative n-type contact shapes and various structure shapes from a plan view according to embodiments.

FIG. 5 shows an illustrative further subsequent intermediate heterostructure for fabricating the optoelectronic device(s) from the wafer according to embodiments.

FIG. 6 shows an illustrative still further subsequent intermediate heterostructure for fabricating the optoelectronic device(s) from the wafer according to embodiments.

FIG. 7 shows an illustrative structure including a plurality of vertical optoelectronic devices which have been fabricated from the wafer according to embodiments.

FIG. 8 shows an illustrative flow diagram for fabricating a circuit according to embodiments.

It is noted that the drawings may not be to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

As indicated above, aspects of the invention provide an optoelectronic device and a method for the fabrication thereof. The optoelectronic device can include a p-type contact and an optoelectronic heterostructure located on the p-type contact. The optoelectronic heterostructure can include a p-type semiconductor layer, an n-type semiconductor layer, and an active region located between the p-type semiconductor layer and the n-type semiconductor layer. An n-type contact can be located on a surface of the optoelectronic heterostructure. Additionally, three-dimensional nanostructures also can be located on the surface of the optoelectronic heterostructure. At least one of: a density, a size, or a shape of the three-dimensional nanostructures can be substantially uniform across the surface of the optoelectronic heterostructure. The method of fabricating the optoelectronic device can include forming the three-dimensional nanostructures on a surface of the heterostructure exposed by removal of a growth substrate. The optoelectronic device can be configured to operate as a deep ultraviolet light emitting device.

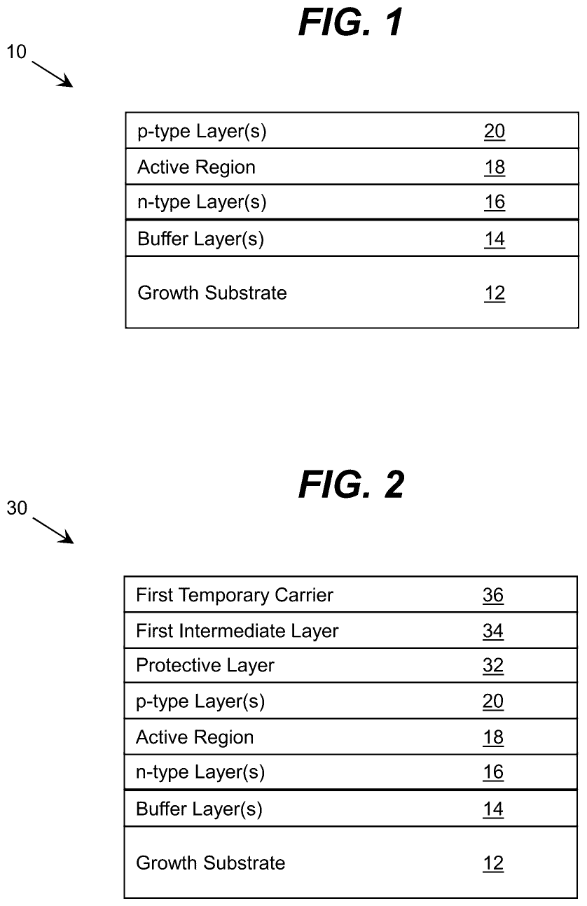

Turning to the drawings, FIG. 1 shows an illustrative wafer 10 for fabricating optoelectronic device(s) according to embodiments.

The wafer 10 includes a heterostructure comprising a growth substrate 12, buffer layer(s) 14 adjacent to the growth substrate 12, n-type layer(s) 16 (e.g., a cladding layer, electron supply layer, contact layer, and/or the like) adjacent to the buffer layer(s) 14, an active region 18 adjacent to the n-type layer(s) 16, and p-type layer(s) 20 (e.g., an electron blocking layer, a cladding layer, hole supply layer, contact layer, and/or the like) adjacent to a p-type side of the active region 18.

In more particular illustrative embodiments, the resulting optoelectronic device(s) are configured to operate as an emitting device, such as a light emitting diode (LED) or a laser diode (LD). In either case, during operation of an optoelectronic device, application of a bias comparable to the band gap results in the emission of electromagnetic radiation from the active region 18 of the optoelectronic device. Alternatively, the optoelectronic device can be configured to operate as a sensing device, such as a photodiode.

Regardless, the electromagnetic radiation emitted (or sensed) by the optoelectronic device can have a peak wavelength within any range of wavelengths, including visible light, ultraviolet radiation, deep ultraviolet radiation, infrared light, and/or the like. In embodiments, the active region 18 is configured to emit (or sense) radiation having at least one dominant wavelength within the ultraviolet range of wavelengths. In more specific embodiments, at least one dominant wavelength is within the deep ultraviolet (DUV) range of wavelengths. In still more specific embodiments, a dominant wavelength is within a range of wavelengths between approximately 225 and approximately 360 nanometers.

In more particular illustrative embodiments, the wafer 10 is configured to form a group III-V materials based optoelectronic device(s), in which some or all of the various layers are formed of elements selected from the group III-V materials system. In still more particular illustrative embodiments, the various layers of the wafer 10 are formed of group III nitride based materials. Group III nitride materials comprise one or more group III elements (e.g., boron (B), aluminum (Al), gallium (Ga), and indium (In)) and nitrogen (N), such that B_{w}AlₓGa_{y}In_{z}N, where 0≤w, x, y, z≤1, and w+x+y+z=1. Illustrative group III nitride materials include binary, ternary and quaternary alloys such as, AlN, GaN, InN, BN, AlGaN, AlInN, AlBN, AlGaInN, AlGaBN, AlInBN, and AlGaInBN with any molar fraction of group III elements.

An illustrative embodiment of a group III nitride based wafer 10 includes a growth substrate 12, which can comprise any material suitable for growing group III nitride layers thereon. In embodiments, the substrate 12 is formed of sapphire. However, it is understood that the substrate 12 can be formed of any suitable material including, for example, silicon carbide (SiC), silicon (Si), a group III-V substrate such as GaAs, bulk GaN, bulk AlN, bulk or a film of AlGaN, bulk or a film of BN, or the like, LiGaO₂, LiAlO₂, aluminum oxinitride (AlOₓN_{y}), MgAl₂O₄, Ge, diamond, aluminum oxide (Al₂O₃), or another suitable material.

In illustrative embodiments, the buffer layer(s) 14 can comprise one or more layers of material configured to provide a suitable growth surface for subsequent growth of the n-type layer(s) 16, active region 18, and p-type layer(s) 20. More particular illustrative embodiments of the buffer layer(s) 14 comprise AlN, an AlGaN/AlN superlattice, and/or the like. Furthermore, to improve growth conditions, a surface of the substrate 12 on which the buffer layer(s) 14 are grown can be patterned using any solution.

Each of the n-type layer(s) 16, the p-type layer(s) 20, and the active region 18 can be composed of an In_{y}AlₓGa_{1-x-y}N alloy, a Ga_{z}In_{y}AlₓB_{1-x-y-z}N alloy, or the like. The active region 18 can include one or more quantum wells, each of which can be configured to emit or sense electromagnetic radiation having a dominant wavelength. In more particular embodiments, the active region 18 can include one or more series of alternating quantum wells and barriers, each of which is composed of In_{y}AlₓGa_{1-x-y}N, Ga_{z}In_{y}AlₓB_{1-x-y-z}N, an AlₓGa₁₋ₓN semiconductor alloy, or the like. The molar fractions given by x, y, and z can vary between the various layers 16, 18, 20. The n-type layer(s) 16 can be intentionally doped with any type of n-type dopant(s), such as silicon (Si), while the p-type layer(s) 20 can be intentionally doped with any type of p-type dopant, such as magnesium (Mg).

In embodiments, the p-type layer(s) 20 can be configured to be transparent to the electromagnetic radiation generated/sensed by the active region 18. For example, a p-type layer 20 can comprise a short period superlattice lattice structure, such as an at least partially transparent magnesium (Mg)-doped AlGaN/AlGaN short period superlattice (SPSL) structure. In embodiments, the n-type layer(s) 16 can be configured to be transparent to the electromagnetic radiation generated/sensed by the active region 18. For example, an n-type layer 16 can be formed of a short period superlattice, such as an AlGaN SPSL.

In embodiments, the wafer 10 can include a sapphire growth substrate 12, an AlN buffer layer 14, an n-doped AlInGaN n-type layer 16, an AlInGaN multi-quantum well (MQW) active region, and a p-doped AlInGaN p-type layer 20. However, it is understood that this is only illustrative of various possible layer configurations and materials for the wafer 10.

In order to fabricate optoelectronic device(s) from the wafer 10, the growth substrate 12 can be removed and a permanent substrate (e.g., carrier) can be attached to the p-type side of the wafer 10.

FIG. 2 shows an illustrative intermediate heterostructure 30 for fabricating the optoelectronic device(s) from the wafer 10 according to embodiments.

As illustrated, a protective layer 32 can be formed (e.g., deposited) on the p-type layer(s) 20. The protective layer 32 can comprise any suitable material capable of protecting the group III nitride layers during the further processing described herein, including multiple flip overs of intermediate structures for formation of new layers, bonding to new carriers, etc. In embodiments, the protective layer 32 can be formed of a silicon oxynitride, such as silicon dioxide (SiO₂), silicon nitride (SiN), and/or the like. In embodiments, the protective layer 32 has a thickness sufficient to provide the desired protection. In further embodiments, the protective layer has a thickness less than or equal to approximately 200 nanometers, e.g., in a range of approximately 100 nanometers to approximately 200 nanometers.

A first intermediate layer 34 can be formed (e.g., deposited) on the protective layer 32. The first intermediate layer 34 can comprise any material having sufficient thermal stability for the subsequent bonding. For example, the first intermediate layer 34 can comprise a high temperature bonding material, which can withstand temperatures of 1000 degrees Celsius or higher. In embodiments, the first intermediate layer 34 can be configured to have sufficient thermal stability up to 1000 degrees Celsius for subsequent realization of n-type ohmic contacts, re-growth of three-dimensional nanostructures, and/or the like. In embodiments, the first intermediate layer 34 is formed of a silicon oxynitride (SiOₓN_{y}), which can be deposited using plasma-enhanced chemical vapor deposition (PECVD) or the like. In embodiments, the first intermediate layer 34 is formed of hydrogen silsesquioxane (HSQ), a flowable oxide which has been used as a spin-on dielectric for fabricating electronic devices through integration of AlGaN/GaN transistors and Si CMOS electronics on the same chip but not in combination with a protective layer 32 and/or for fabricating optoelectronic device(s) as described herein. In embodiments, the first intermediate layer 34 has a thickness less than approximately 100 nanometers, e.g., in a range of approximately 80 nanometers to approximately 120 nanometers.

A first temporary carrier 36 can be bonded to the protective layer 32 using a bonding attribute of the first intermediate layer 34. For example, the first temporary carrier 36 can be bonded to the protective layer 32 via the first intermediate layer 34 using any solution, such as conventional wafer direct-bonding technologies or surface activated bonding. In embodiments, the bonding can utilized thermo-compression, e.g., when the first intermediate layer 34 is formed of hydrogen silsesquioxane (HSQ). In embodiments, the first temporary carrier 36 can be formed of sapphire, Si, SiC, a group III-V substrate such GaAs, diamond, alumina, or the like substrate materials.

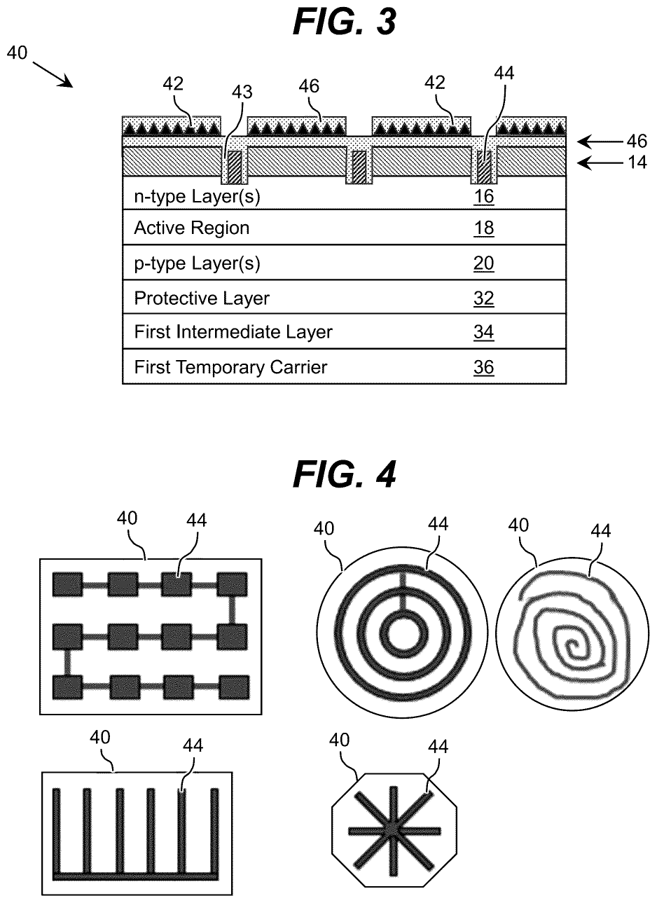

FIG. 3 shows an illustrative subsequent intermediate heterostructure 40 for fabricating the optoelectronic device(s) from the wafer 10 (FIG. 1) according to embodiments.

As shown in FIG. 3, the growth substrate 12 (FIG. 2) can be removed using any solution, such as LLO, or the like. Subsequently, the exposed N-face buffer layer 14 can be either completely or partially etched using any solution.

Three-dimensional (3D) nanostructures 42 can be formed on the surface of a partially etched buffer layer 14 or an exposed surface of an n-type layer 16 (e.g., when the buffer layer 14 has been completely removed) using any solution. In embodiments, the nanostructures 42 are formed of a group III nitride material, such as AlGaN. In embodiments, the nanostructures 42 are formed by selective area growth (SAG) through submicron window openings within a patterned dielectric mask 46 (e.g., SiO₂, SiN, or the like). Such regrowth can be performed at temperatures between 700 and 1000 degrees Celsius.

Each nanostructure 42 can be grown into a hexagonal pyramid, truncated pyramid, circular cone, and/or the like, e.g., using physical vapor deposition (PVD), metal-organic chemical vapor deposition (MOCVD), molecular beam epitaxy (MBE), or the like. The density, size, and shape of the nanostructures 42 can be controlled by adjusting the dimensions, locations, pitch, etc., of the window openings within the dielectric mask as well as through growth conditions for the nanostructures 42. The nanostructures 42 can be substantially uniform in density, size, and/or shape across a surface of the structure 40, unlike structures formed by a wet etching process. In embodiments, the lateral size of the nanostructures can be comparable to the effective wavelength of the electromagnetic radiation, λ_{c}, that will be generated (or sensed) by the active region 18. For example, the lateral size of the nanostructures can be approximately λ_{c}/n_{ref}, where n_{ref} is the refractive index of the nanostructure material.

In embodiments, the nanostructures 42 can be fabricated using self-organized AlGaN 3D islands, also called quantum dots (QDs). In embodiments, the fabrication of the nanostructures 42 can follow a 2D-3D growth mode transition (also called Stranski-Krastanov growth mode) during the deposition of compressively strained AlGaN layers on the N-face surface of the n-type layer 16 and/or the buffer layer 14. Since the QDs are usually small (e.g., <20 nm in diameter), deposition of additional material species can be used to further increase their sizes, e.g., up to the level of λ_{c}/n_{ref}, while still maintaining a rough surface. This can be accomplished by optimizing the nanostructures 42 growth conditions. Another technique to achieve larger size nanostructures can use a Volmer-Weber growth mode, which involves direct 3D islands formation, instead of the 2D-3D growth mode transition mentioned above.

Vias 43 can be formed in the buffer layer 14, the dielectric mask 46, and/or nanostructures 42 to access the n-type layer(s) 16 using any solution. In embodiments, the vias 43 can be formed by chemical etching using standard photolithography. In embodiments, the vias 43 can extend partially into an n-type layer 16. Subsequently, the n-type ohmic contacts 44 can be formed on the exposed n-type layer(s) 16 using any solution. For example, the n-type ohmic contacts 44 can be formed by depositing a multi-layer metal stack on the n-type layer(s) 16 and annealing at temperatures greater than 800 degrees Celsius. In embodiments, the n-type ohmic contacts 44 can comprise any suitable metal stack used in LEDs, such as in lateral conduction DUV LEDs.

The structure 40 can be coated with a second protective layer 46, which can comprise a dielectric layer, such as silicon dioxide, or the like. The second protective layer 46 can be relatively thin, e.g., less than approximately 100 nanometers, but generally cover the nanostructures 42 and the n-type ohmic contacts 44. The protective layer 46 may partially or completely fill the vias 43 including the n-type ohmic contacts 44.

It is understood that the structure 40 and the ohmic contacts 44 can have any of various shapes when viewed from the plan view. To this extent, FIG. 4 shows various illustrative n-type contact 44 shapes and various structure 40 shapes from a plan view according to embodiments. In embodiments, the n-type contact 44 shapes are configured to provide comprehensive coverage over an area of the structure 40 while also reducing the area covered by the n-type contact 44 in order to facilitate emission of electromagnetic radiation from the device. However, it is understood that the various shapes shown in FIG. 4 are only illustrative of numerous possible shapes for the structure 40 and the n-type contacts 44.

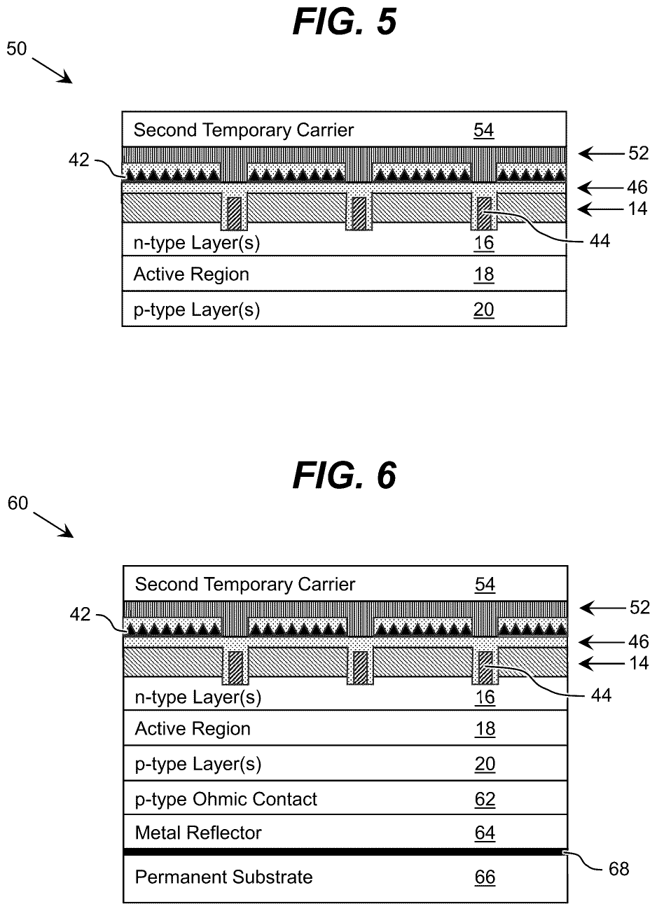

FIG. 5 shows an illustrative further subsequent intermediate heterostructure 50 for fabricating the optoelectronic device(s) from the wafer 10 (FIG. 1) according to embodiments.

As shown in FIG. 5, after application of the second protective layer 46, a second intermediate layer 52 can be formed on the second protective layer 46. The second intermediate layer 52 can be configured similar to the first intermediate layer 34 (FIG. 2) described herein. In embodiments, the second intermediate layer 52 is formed of silicon oxynitride (SiOₓN_{y}), HSQ, or the like. In embodiments, the second protective layer 46 has a thickness less than approximately 100 nanometers, e.g., in a range of 80 nanometers to 120 nanometers.

A second temporary carrier 54 can be bonded to the second intermediate layer 52 using any solution, such as conventional wafer direct-bonding technologies or surface activated bonding. The second temporary carrier 54 can be configured similar to the first temporary carrier 36 (FIG. 2) described herein. In embodiments, the second temporary carrier 54 can be formed of sapphire, Si, SiC, a group III-V substrate such GaAs, diamond, alumina, or the like substrate materials.

With the second temporary carrier 54 secured to the heterostructure 50, the first temporary carrier 36, first intermediate layer 34, and protective layer 32 shown in FIG. 3 can be removed from the heterostructure 50 using any solution. For example, the first temporary carrier 36 and layers 32, 34 can be removed with selective wet etches. After removal, a surface of the p-type layer(s) 20 will be exposed.

FIG. 6 shows an illustrative still further subsequent intermediate heterostructure 60 for fabricating the optoelectronic device(s) from the wafer 10 (FIG. 1) according to embodiments.

A p-type ohmic contact 62 can be formed adjacent to the exposed surface of the p-type layer(s) 20 using any solution. In embodiments, the p-type ohmic contact 62 can comprise several conductive and reflective metal layers. In this case, the p-type ohmic contact 62 can be formed by depositing a multi-layer metal stack on the p-type layer(s) 20 and annealing, e.g., at temperatures of approximately 500 degrees Celsius. In embodiments, the p-type ohmic contact 62 can comprise any suitable metal stack used in LEDs, such as in lateral conduction DUV LEDs. In embodiments, the p-type layer(s) 20 can be configured to be transparent and the p-type ohmic contact 62 can be configured to be highly reflective to the electromagnetic radiation generated/sensed by the active region 18. In this case, the p-type layer(s) 20 can comprise a very thin (Mg)-doped GaN, with a thickness of less than 5 nm, and/or a short period superlattice lattice (SPSL) structure, such as an at least partially transparent magnesium (Mg)-doped AlGaN/AlGaN short period superlattice (SPSL) structure.

However, it is understood that this configuration is only illustrative. In other embodiments, the p-type layer(s) 20 and the p-type ohmic contact 62 can be configured to be transparent to the electromagnetic radiation generated/sensed by the active region 18. In this case, the p-type layer(s) 20 and/or the p-type ohmic contact 62 can comprise a short period superlattice lattice structure, such as an at least partially transparent magnesium (Mg)-doped AlGaN/AlGaN short period superlattice structure (SPSL).

In embodiments, a metal reflector 64 can be formed adjacent to the p-type ohmic contact 62 using any solution. The metal reflector 64 can be formed of any material reflective of the electromagnetic radiation generated/sensed by the active region 18, which can be configured to further increase an amount of electromagnetic radiation emitted by the resulting optoelectronic device(s), e.g., through the n-type layer(s) 16. In embodiments, the metal reflector 64 comprises aluminum, which can be deposited on the p-type ohmic contact 62 using any solution.

A permanent substrate 66 can be bonded to the metal reflector 64 using, for example, a metal-to-metal bond 68. In embodiments, the permanent substrate 66 can be formed of any suitable substrate material having high thermal conductivity. For example, the permanent substrate 66 can comprise a metallic plate or a semiconductor carrier such as AlN, Si, SiC, III-V materials such as GaAs, ceramics such as alumina, and/or the like. The bond 68 can be any suitable bond for bonding the materials of the metal reflector 64 and permanent substrate 66, such as solder, metal-to-metal thermo-compression, and/or the like.

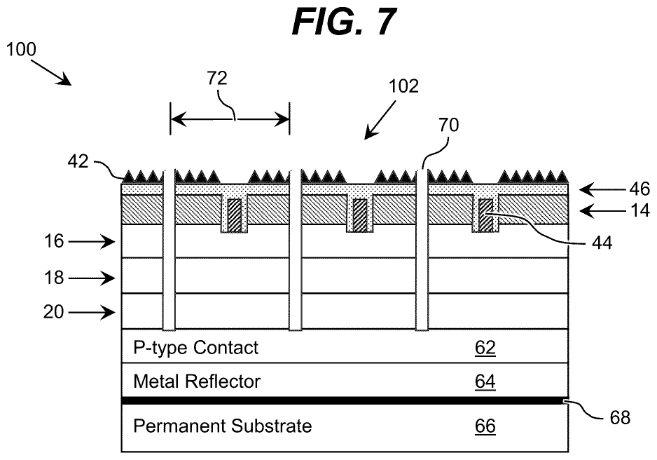

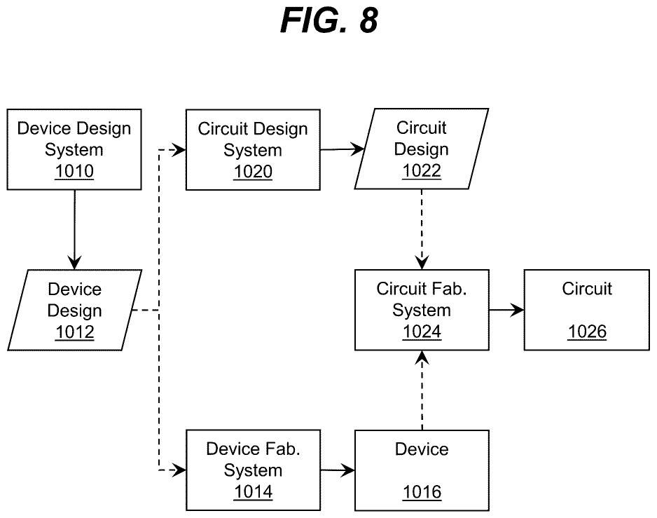

FIG. 7 shows an illustrative structure 100 including a plurality of vertical optoelectronic devices 102 which have been fabricated from the wafer 10 (FIG. 1) according to embodiments. After the permanent substrate 66 has been added to the structure, the second temporary carrier 54 and second intermediate layer 52 shown in FIG. 6 can be removed using any solution. For example, the second temporary carrier 54 and second intermediate layer 52 can be removed with selective wet etches. In embodiments, the second protective layer 46 also can be thinned down to match the shape of the underlying nanostructures 42, or completely removed, e.g., using dry or wet chemical etching, such that the top surface is rough to enhance light extraction.

After removal of the second temporary carrier and second intermediate layer and selective etching of protective layer 46 on top of the nanostructures 42, the structure 100 is configured for inclusion in a circuit and operation as a vertical optoelectronic device. As further shown in FIG. 7, in embodiments, the structure 100 can be further processed to create a plurality of vertical optoelectronic device 102 from the structure 100. For example, as illustrated, trenches 70 can be formed in the structure 100 to form a plurality of individual vertical optoelectronic devices 102 having desired widths 72. In embodiments, the optoelectronic devices 102 can have a rectangular shape from a plan view. However, it is understood that optoelectronic devices 102 can have any of the shapes illustrated in FIG. 4 from the plan view. The trenches 70 can be formed using any solution, such as etching, laser dicing, or the like. As illustrated, the individual vertical optoelectronic devices 102 can share a common p-type contact 62. However, if desired, individual optoelectronic devices 102 or smaller groups of optoelectronic devices 102 that share a common p-type contact 62 can be formed by extending some or all of the trenches 70 through the entire structure 100.

While illustrative aspects of the invention have been shown and described herein primarily in conjunction with a heterostructure for an optoelectronic device and a method of fabricating such a heterostructure and/or device, it is understood that aspects of the invention further provide various alternative embodiments.

In one embodiment, the invention provides a method of designing and/or fabricating a circuit that includes one or more of the devices designed and fabricated as described herein. To this extent, FIG. 8 shows an illustrative flow diagram for fabricating a circuit 1026 according to embodiments. Initially, a user can utilize a device design system 1010 to generate a device design 1012 for a semiconductor device, such as a vertical optoelectronic device, as described herein. The device design 1012 can comprise program code, which can be used by a device fabrication system 1014 to generate a set of physical devices 1016 according to the features defined by the device design 1012. Similarly, the device design 1012 can be provided to a circuit design system 1020 (e.g., as an available component for use in circuits), which a user can utilize to generate a circuit design 1022 (e.g., by connecting one or more inputs and outputs to various devices included in a circuit). The circuit design 1022 can comprise program code that includes a device designed as described herein. In any event, the circuit design 1022 and/or one or more physical devices 1016 can be provided to a circuit fabrication system 1024, which can generate a physical circuit 1026 according to the circuit design 1022. The physical circuit 1026 can include one or more devices 1016 designed as described herein.

In another embodiment, the invention provides a device design system 1010 for designing and/or a device fabrication system 1014 for fabricating a semiconductor device 1016, such as a vertical optoelectronic device, as described herein. In this case, the system 1010, 1014 can comprise a general purpose computing device, which is programmed to implement a method of designing and/or fabricating the semiconductor device 1016 as described herein. Similarly, an embodiment of the invention provides a circuit design system 1020 for designing and/or a circuit fabrication system 1024 for fabricating a circuit 1026 that includes at least one device 1016 designed and/or fabricated as described herein. In this case, the system 1020, 1024 can comprise a general purpose computing device, which is programmed to implement a method of designing and/or fabricating the circuit 1026 including at least one semiconductor device 1016 as described herein.

In still another embodiment, the invention provides a computer program fixed in at least one computer-readable medium, which when executed, enables a computer system to implement a method of designing and/or fabricating a semiconductor device, such as a vertical optoelectronic device, as described herein. For example, the computer program can enable the device design system 1010 to generate the device design 1012 as described herein. To this extent, the computer-readable medium includes program code, which implements some or all of a process described herein when executed by the computer system. It is understood that the term “computer-readable medium” comprises one or more of any type of tangible medium of expression, now known or later developed, from which a stored copy of the program code can be perceived, reproduced, or otherwise communicated by a computing device.

In another embodiment, the invention provides a method of providing a copy of program code, which implements some or all of a process described herein when executed by a computer system. In this case, a computer system can process a copy of the program code to generate and transmit, for reception at a second, distinct location, a set of data signals that has one or more of its characteristics set and/or changed in such a manner as to encode a copy of the program code in the set of data signals. Similarly, an embodiment of the invention provides a method of acquiring a copy of program code that implements some or all of a process described herein, which includes a computer system receiving the set of data signals described herein, and translating the set of data signals into a copy of the computer program fixed in at least one computer-readable medium. In either case, the set of data signals can be transmitted/received using any type of communications link.

In still another embodiment, the invention provides a method of generating a device design system 1010 for designing and/or a device fabrication system 1014 for fabricating a semiconductor device as described herein. In this case, a computer system can be obtained (e.g., created, maintained, made available, etc.) and one or more components for performing a process described herein can be obtained (e.g., created, purchased, used, modified, etc.) and deployed to the computer system. To this extent, the deployment can comprise one or more of: (1) installing program code on a computing device; (2) adding one or more computing and/or I/O devices to the computer system; (3) incorporating and/or modifying the computer system to enable it to perform a process described herein; and/or the like.

As used herein, unless otherwise noted, the term “set” means one or more (i.e., at least one) and the phrase “any solution” means any now known or later developed solution. The singular forms “a,” “an,” and “the” include the plural forms as well, unless the context clearly indicates otherwise. Additionally, the terms “comprises,” “includes,” “has,” and related forms of each, when used in this specification, specify the presence of stated features, but do not preclude the presence or addition of one or more other features and/or groups thereof.

As also used herein, a layer is a transparent layer when the layer allows at least ten percent of radiation having a target wavelength, which is radiated at a normal incidence to an interface of the layer, to pass there through. Furthermore, as used herein, a layer is a reflective layer when the layer reflects at least ten percent of radiation having a target wavelength, which is radiated at a normal incidence to an interface of the layer. In an embodiment, the target wavelength of the radiation corresponds to a wavelength of radiation emitted or sensed (e.g., peak wavelength +/−five nanometers) by an active region of an optoelectronic device during operation of the device. For a given layer, the wavelength can be measured in a material of consideration and can depend on a refractive index of the material. Additionally, as used herein, a contact is considered “ohmic” when the contact exhibits close to linear current-voltage behavior over a relevant range of currents/voltages to enable use of a linear dependence to approximate the current-voltage relation through the contact region within the relevant range of currents/voltages to a desired accuracy (e.g., +/−one percent).

It is understood that, unless otherwise specified, each value is approximate and each range of values included herein is inclusive of the end values defining the range. Terms of degree such as “generally,” “substantially,” “about,” and “approximately” as used herein mean a reasonable amount of deviation of the modified term such that the end result is not significantly changed. For example, these terms can be construed as including a deviation of at least +/−0.5% of the modified term if this deviation would not negate the meaning of the word it modifies. In a more particular example, the term “approximately” is inclusive of values within +/−ten percent of the stated value, while the term “substantially” is inclusive of values within +/−five percent of the stated value when these deviations would not negate the meaning of the word each term modifies. Unless otherwise stated, two values are “similar” when the amount of deviation between the two values does not significantly change the result. In a more particular example, two values are similar when the smaller value is within +/−twenty-five percent of the larger value. A value, y, is on the order of a stated value, x, when the value y satisfies the formula 0.1x≤y≤10x.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to an individual in the art are included within the scope of the invention as defined by the accompanying claims.

What is claimed is:

1. An optoelectronic device comprising:
a permanent substrate;
a p-type contact located on the permanent substrate;
at least one optoelectronic heterostructure located on the p-type contact, the at least one optoelectronic heterostructure including a p-type semiconductor layer, an n-type semiconductor layer, and an active region located between the p-type semiconductor layer and the n-type semiconductor layer;
at least one n-type contact located on a surface of the at least one optoelectronic heterostructure; and
a plurality of three-dimensional nanostructures located on the surface of the at least one optoelectronic heterostructure, wherein at least one of: a density, a size, or a shape of the three-dimensional nanostructures is substantially uniform across the surface of the at least one optoelectronic heterostructure.

2. The device of claim 1, further comprising a metal reflector located between the permanent substrate and the p-type contact.

3. The device of claim 2, wherein the permanent substrate is bonded to the metal reflector using a metal-to-metal bond.

4. The device of claim 1, wherein the at least one optoelectronic heterostructure further includes a barrier layer located on the n-type semiconductor layer.

5. The device of claim 4, wherein the at least one n-type contact is located in at least one via formed in the barrier layer.

6. The device of claim 1, further comprising a protective layer located adjacent to the plurality of nanostructures and the n-type contact on the at least one optoelectronic heterostructure.

7. The device of claim 1, further comprising at least one trench dividing the at least one optoelectronic heterostructure into a plurality of optoelectronic heterostructures that share the p-type contact.

8. The device of claim 1, wherein the active region is configured to emit deep ultraviolet radiation.

9. A deep ultraviolet light emitting device comprising:
a p-type contact;
a heterostructure located on the p-type contact, the heterostructure including a p-type semiconductor layer, an n-type semiconductor layer, and an active region located between the p-type semiconductor layer and the n-type semiconductor layer, wherein the active region is configured to emit deep ultraviolet radiation;
at least one n-type contact located on a surface of the heterostructure; and
a plurality of three-dimensional nanostructures located on the surface of the heterostructure, wherein at least one of: a density, a size, or a shape of the three-dimensional nanostructures is substantially uniform across the surface of the heterostructure.

10. The device of claim 9, further comprising a metal reflector located below the p-type contact.

11. The device of claim 9, wherein the heterostructure further includes a barrier layer located on the n-type semiconductor layer.

12. The device of claim 11, wherein the at least one n-type contact is located in at least one via formed in the barrier layer.

13. The device of claim 9, further comprising a protective layer located adjacent to the plurality of nanostructures and the n-type contact on the heterostructure.

14. A method of fabricating an optoelectronic device, the method comprising:
removing a growth substrate from a wafer, the wafer comprising a heterostructure located on the growth substrate, the heterostructure including: a buffer layer located on the growth substrate, an n-type semiconductor layer located on the buffer layer, a p-type semiconductor layer located on the n-type semiconductor layer, and an active region located between the n-type semiconductor layer and the p-type semiconductor layer; and
forming a plurality of three-dimensional nanostructures on a surface of the heterostructure exposed by removal of the growth substrate, wherein at least one of: a density, a size, or a shape of the three-dimensional nanostructures is substantially uniform across the surface of the heterostructure.

15. The method of claim 14, wherein the forming includes selective area growth of the three-dimensional nanostructures through submicron window openings within a patterned dielectric mask.

16. The method of claim 14, wherein the forming includes fabricating self-organized three-dimensional islands using a Stranski-Krastanov growth mode or a Volmer-Weber growth mode.

17. The method of claim 14, further comprising:
applying a first temporary carrier to the wafer prior to removing the growth substrate, wherein the applying includes applying a first intermediate layer on the p-type layer and bonding the first temporary carrier to the first intermediate layer, wherein the first intermediate layer comprises hydrogen silsesquioxane (HSQ); and
removing the first temporary carrier and the first intermediate layer after the forming.

18. The method of claim 17, further comprising forming at least one n-type contact prior to removing the first temporary carrier and the first intermediate layer, the forming at least one n-type contact including:
forming at least one via to expose a surface of the n-type layer; and
forming the at least one n-type contact in the at least one via.

19. The method of claim 17, further comprising applying a second temporary carrier on the plurality of three-dimensional nanostructures prior to removing the first temporary carrier and the first intermediate layer, wherein the applying the second temporary carrier includes:
applying a second intermediate layer on the plurality of three-dimensional nanostructures, wherein the second intermediate layer comprises hydrogen silsesquioxane (HSQ); and
bonding the second temporary carrier to the second intermediate layer.

20. The method of claim 19, further comprising:
forming a p-type contact adjacent to the p-type layer; and
removing the second intermediate layer and the second temporary carrier after forming the p-type contact.
